(19) United States
(12) Patent Application Publication
(10) Pub. No.: US 2004/0070428 A1
(43) Pub. Date: Apr. 15, 2004

(54) Circuit for generating a linear current control signal and method thereof

(76) Inventor: Chao-Ching Chen, Kaohsiung (TW)

Correspondence Address: BIRCH STEWART KOLASCH & BIRCH, PO BOX 747, FALLS CHURCH, VA, 22040-0747, US

(21) Appl. No.: 10/307,372

(22) Filed: Dec. 2, 2002

(30) Foreign Application Priority Data
Oct. 11, 2002 (TW) 91123417

(51) Int. Cl. H03D 1/00

(52) U.S. Cl. 327/103

(57) ABSTRACT

A circuit for generating a linear current control signal and method thereof is provided so that the error between the input voltage and the linear current remains constant. The circuit of the invention comprises a resistor, an operational amplifier and a MOSFET, which forms an ideal linear relationship between an input voltage and an output current. The operational amplifier generates a gate-controlled voltage when a reference voltage and an input voltage are inputted thereto. The gate voltage turns on the MOSFET so that a linear current control signal is outputted from the source of the MOSFET.

### BACKGROUND OF THE INVENTION

1. Field of Invention

The invention is related to a control circuit, and more particularly a control circuit for generating a linear current control signal.

2. Related Art

A precise and stable control signal is often employed to control an apparatus or a device to perform an expected operation. The control signals are classified as voltage control signal and current control signal wherein the 0˜20 mA current control signal is widely used.

A linear current control signal is ideal to perform a precise control. However, a variable error is generated owing to the limitation of the characteristics of the circuit and the components so that the relationship between the input voltage signal and the output current signal is often not linear. The nonlinear current control signal having a variable error is not ideal for control.

A prior art of a circuit for generating current control signal is shown in FIG. 1. As shown in the figure, the circuit comprises a first operation amplifier 11, a second operation amplifier 12, a first resistor R1, a second resistor R2, a third resistor R3, a fourth resistor R4, and a fifth resistor R5. The reference number VIN stands for the input voltage signal of the circuit while IO stands for the output current control signal. Two equations are obtained from the circuit shown in FIG. 1.

$${V}_{-} = ( \frac{{R}_{1}}{{R}_{1} + {R}_{2}} ) * {V}_{P} , {V}_{P} = ( \frac{{R}_{1} + {R}_{2}}{{R}_{1}} ) * {V}_{-} , \qquad ( Formula 1 )$$

$$\frac{( {V}_{P} - {R}_{5} {I}_{O} ) - {V}_{+}}{{R}_{4}} + \frac{{V}_{IN} - {V}_{+}}{{R}_{3}} = 0. \qquad ( Formula 2 )$$

Substitute

$${V}_{P} = ( \frac{{R}_{1} + {R}_{2}}{{R}_{1}} ) * {V}_{-} into \frac{( {V}_{P} - {R}_{5} {I}_{O} ) - {V}_{+}}{{R}_{4}} + \frac{{V}_{IN} - {V}_{+}}{{R}_{3}} = 0 ,$$

we obtain another equation as follows:

$${I}_{O} = \frac{{R}_{4}}{{R}_{5} {R}_{3}} * {V}_{IN} + ( \frac{{R}_{1} + {R}_{2}}{{R}_{5} {R}_{1}} ) * {V}_{-} - ( \frac{{R}_{3} + {R}_{4}}{{R}_{5} {R}_{3}} ) * {V}_{+} \qquad ( Formula 3 )$$

Formula 3 can be simplified as

I_{O}=K*V_{IN}+D (Formula 4)

The coefficient K in Formula 4 is a constant

$$( \frac{{R}_{4}}{{R}_{5} {R}_{3}} ) ,$$

while D is an error.

$$( ( \frac{{R}_{1} + {R}_{2}}{{R}_{5} {R}_{1}} ) * {V}_{-} - ( \frac{{R}_{3} + {R}_{4}}{{R}_{5} {R}_{3}} ) * {V}_{+} ) .$$

Considering K and D as constants, the output current control signal 10 is proportional to the input voltage signal V_{IN}. But in reality the error D is variable owing to the following reasons. First, the resistors R1, R2, R3 and R4 are not ideal components. Second, A bias current V_{BIAS} and a bias voltage V_{OFFSET often} exists between the two inputs V₊ and V₋ of the operational amplifier, i.e., V₋=V₊+V_{OFFSET}+V_{BIAS}. Furthermore, V₋ and V₊ vary with the output current control signal IO. Therefore, it is not possible in reality to keep the error D a constant or even zero. In other words, the output current control signal has a variable error in response to the input voltage signal so that precise control is not easily achieved.

It seems that employing high quality components is the only way to reduce the error of the circuit. However, the variable error can only be lowered and not wholly eliminated by choosing high quality resistors as the circuit components. The output current control signal still comprises a variable error such that the signal becomes nonlinear. Besides, the high quality components are much more expensive and increase the cost of the circuit. It can be concluded that a circuit is necessary that can generate linear current control signals as ideally as possible.

### SUMMARY OF THE INVENTION

Accordingly, an object of the invention is to provide a circuit for generating a linear current control signal thereby reducing the variable error that affects the output current.

The foregoing object of the invention is achieved through the provision of an operation amplifier, a resistor and a gate-controlled component. The circuit for generating linear current control signals of the invention has an operation amplifier, a resistor and a MOSFET. The operation amplifier having a first voltage input end and a second voltage input end is employed for outputting a gate-controlled voltage in response to an input voltage and a reference voltage. The resistor coupled to the first voltage input end is used for generating a linear current in response to the reference voltage. The drain of the MOSFET is also coupled to the first voltage input end of the operation amplifier. The gate of the MOSFET is coupled to the voltage output end. When the gate voltage is greater than the threshold voltage of the MOSFET, linear current is outputted as a linear output current via the MOSFET.

Further scope of applicability of the invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

FIG. 1 shows the circuit of the prior art for generating a linear current control signal.

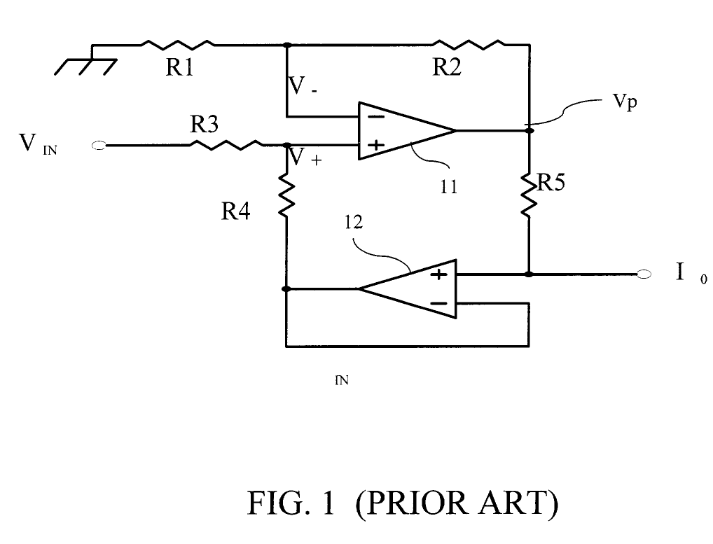

FIG. 2 shows the circuit of the invention for generating a linear current control signal.

FIG. 3 is a relationship chart showing the relationship between of input voltage and the output current of the circuit of the invention.

### DETAILED DESCRIPTION OF THE INVENTION

The method of generating linear current control signals of the invention is based on an operation amplifier and a voltage controlled component. The operation amplifier outputs a gate-controlled voltage in response to an input voltage and a reference. When the gate-controlled voltage is greater than the threshold voltage of the gate-controlled component, a linear output current is outputted via the gate-controlled component.

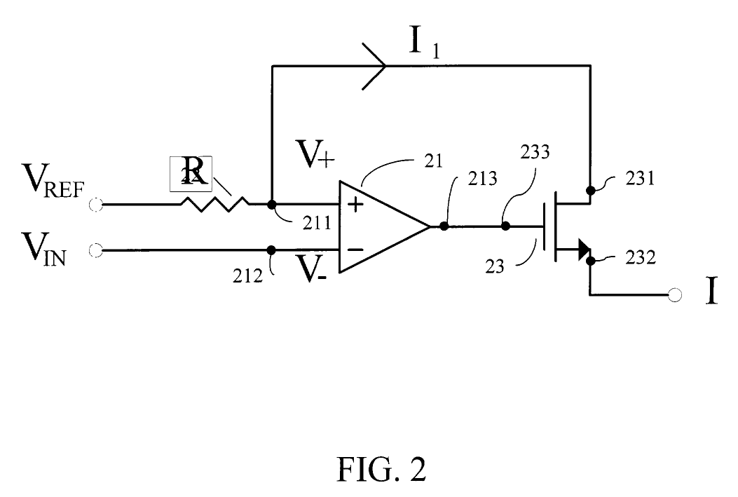

As shown in the FIG. 2, the circuit for generating a linear current control signal has an operation amplifier 21, an impedance component 22 and a voltage-controlled component 23. The preferred embodiment of the impedance component is a resistor, while the voltage-controlled component 23 is a MOSFET.

The operation amplifier 21 has a first voltage input end 211, a second voltage input end 212 and a voltage output end 213. The resistor 22 is coupled to the first voltage input end 211 of the operation amplifier 21. The MOSFET 23 has a drain 231, a source 232, and a gate 233. The drain 231 of the MOSFET 23 is coupled to the first voltage input end 211 of the operation amplifier 21. The gate 233 is coupled to the voltage end 213 of the operation amplifier 21.

The linear current control signal disclosed by the invention is generated by a reference voltage. The reference voltage is outputted as a linear voltage by the resistor 22. A linear current is then obtained by the linear voltage divided by the value of the resistor 22. The operation amplifier 21 is employed for outputting a gate-controlled voltage in response to a linear voltage and an input voltage. The ON or OFF state of the MOSFET 23 is determined by the gate-controlled voltage. When the gate-controlled voltage is greater than the threshold voltage, the MOSFET 23 turns ON so that the linear current obtained by the resistor 22 is outputted as a linear output current via the MOSFET 23.

In other words, a linear voltage is obtained by the reference voltage via the resistor 22. A gate-controlled voltage is outputted by an operation amplifier 21 used for comparing the reference voltage and the input voltage, thereby controlling the On-Off state of the MOSFET 23. When the MOSFET 23 turns on, the reference voltage is outputted as a linear output current via the MOSFET 23.

A capacitor coupled in parallel between the drain 231 and the source 232 of the MOSFET 23 is used to filter noise so that the output current is more stable.

How a linear current control signal is obtained by the circuit of the invention is explained as follows.

The first input end 211 and the second input end 212 of the operation amplifier 21 are V+ and V− respectively, while I1 is the node current. The reference voltage, the input voltage and the linear output current are marked as V_{REF}, V_{IN}, and I_{O} respectively.

A formula is obtained from the circuit:

$${I}_{1} = \frac{{V}_{REF} - {V}_{+}}{R} \qquad ( Formula 5 )$$

The relationship between the bias current VBIAS and offset voltage V_{OFFSET} of the operation amplifier 21 is as follows:

V_{IN}=V₋=V₊+V_{OFFSET}+V_{BIAS}=>V₁=V_{IN}−(V_{OFFSET}+V_{BIAS}) (Formula 6)

Substituting Formula 6 into Formula 5, we obtain Formula 7 by the voltage-controlled characteristics of the MOSFET 23, i.e., IO=I1.

$${I}_{O} = \frac{- {V}_{IN}}{R} + \frac{{V}_{REF} + {V}_{OFFSET} + {V}_{BIAS}}{R} \qquad ( Formula 7 )$$

Formula 7 can be simplified as

I_{O}=K₁*V_{IN}+D₁ (Formula 8)

K1 is the slope of Formula 8. We can see clearly from Formula 8 that the slope K1

$$( \frac{- 1}{R} )$$

and the error

$${D}_{1} ( \frac{{V}_{REF} + {V}_{OFFSET} + {V}_{BIAS}}{R} )$$

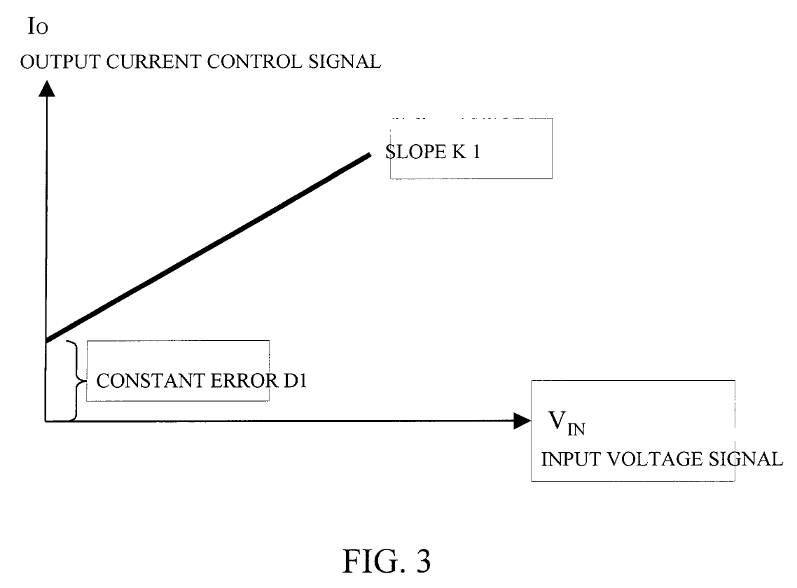

are constant. As long as the error D1 is a constant, the relationship between the output current control signal I_{O} and the input voltage signal V_{IN} is linear. FIG. 3 shows the relationship between the output current control signal I_{O} and the input voltage signal V_{IN}.

It is concluded that an input voltage is outputted as a linear current by the circuit of the invention to achieve the object of precise control. The relationship between the output current control signal I_{O} and the input voltage signal V_{IN} is almost linear because the error of the circuit of the invention is a constant. The nonlinear situation of the current control signal is perfectly overcome by the circuit of the invention. It should be emphasized that normal components are used to implement the circuit of the invention instead of high quality and expensive components.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A circuit for generating linear current control signal, which generates a linear output current in response to an input voltage, comprising:
an impedance component for inputting a reference voltage and outputting a linear voltage;
an operation amplifier for outputting a gate-controlled voltage in response to the linear voltage and the input voltage; and
a voltage-controlled component for outputting the linear voltage as the linear output current when the gate-controlled voltage is greater than the threshold voltage of the gate-controlled component.

2. The circuit for generating linear current control signal of claim 1, wherein the impedance component is a resistor.

3. The circuit for generating linear current control signal of claim 1, wherein the voltage-controlled component turns ON when the gate-controlled voltage is greater than the threshold voltage of the voltage-controlled component.

4. The circuit for generating linear current control signal of claim 1, wherein the voltage-controlled component is a MOSFET having drain, source and gate.

5. The circuit for generating linear current control signal of claim 4, further comprising a capacitor coupled in parallel between the source and the drain of the MOSFET for filtering noise.

6. A circuit for generating linear current control signal, which generates a linear output current in response to an input voltage, comprising:
an operation amplifier having a first voltage input end and a second input end for outputting a gate-controlled voltage in response to the input voltage and a reference voltage;
a resistor being coupled to the first voltage input for generating a linear current in response to the reference voltage; and
a MOSFET having a drain coupled to the first voltage input end, a gate coupled to the voltage output end, and a source, for outputting the linear current as the linear output current when the gate-controlled voltage is greater than the threshold voltage of the MOSFET.

7. The circuit for generating linear current control signal of claim 6, further comprising a capacitor coupled in parallel between the source and the drain of the MOSFET for filtering noise.

8. A method for generating a linear current control signal, comprising:
inputting a reference voltage and a input voltage;
outputting a linear voltage in response to the reference voltage;
outputting a gate-controlled voltage in response to the reference voltage and the input voltage; and
employing the gate-controlled voltage to control the On-Off state of a voltage-controlled component, and outputting the linear voltage as a linear output current when the gate-controlled voltage is greater than the threshold voltage of the voltage-controlled component.

9. The method of claim 8, wherein the voltage-controlled component is a MOSFET.
